(19) United States
(12) Patent Application Publication
(10) Pub. No.: US 2008/0207045 A1
(43) Pub. Date: Aug. 28, 2008

(54) Connector, metal housing and manufacturing method thereof

(75) Inventors: Yu-Yuan Tai, Taoyuan Hsien (TW); Zhao-Wei Guan, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/987,231

(22) Filed: Nov. 28, 2007

(30) Foreign Application Priority Data
Feb. 26, 2007 (TW) 96106354

(51) Int. Cl. H01R 13/73; H05K 7/10; H01R 43/00

(52) U.S. Cl. 439/533; 248/226.12; 29/33 M

(57) ABSTRACT

A connector, a metal housing and a manufacturing method thereof are disclosed. The connector includes a base and a metal housing. The metal housing covers the base and includes a body and at least one ground pin. The ground pin is integrally formed with the body as a single piece and is stamped without a waste material produced. The method for manufacturing the metal housing includes steps of: providing a body; processing the body at a predetermined distance from a fringe of the body to cut out at least one strip; and bending the strip to form a ground pin protruding out of the fringe of the body.

This Non-provisional application claims priority under U.S.C. § 119(a) on Patent Application No(s). 096106354, filed in Taiwan, Republic of China on Feb. 26, 2007, the entire contents of which are hereby incorporated by reference.

### BACKGROUND OF THE INVENTION

1. Field of the Invention

The invention relates to a connector, and in particular to a connector and a metal housing without waste material and manufacturing method thereof.

2. Description of the Related Art

As the technology is in great progress, the electronic products performing information processing, such as computer, tends to be more commonly used. To provide more convenient information processing, electronic devices require connectors with stable transmission quality. Electromagnetic radiation produced by high-density electronic components can result in low-quality transmission. To solve this problem, connectors usually have a metal housing to block electromagnetic radiation and other signals.

A metal housing of a conventional connector is shown in FIGS. 1A, 1B and 1C. FIG. 1A is a schematic view of the conventional metal housing. FIG. 1B is a side view of the metal housing shown in FIG. 1A before cutting. FIG. 1C is a side view of the metal housing shown in FIG. 1B after cutting. In order to allow the metal housing 1 to have functions of grounding and immobility, a metal pin 13 is formed on a side surface 15, close to a fringe 151 of a body 11 of the metal housing 1, in order to be fixed to a circuit board. However, during production, the area near the metal pin 13 is cut off, thereby producing a waste material 16.

### BRIEF SUMMARY OF THE INVENTION

The present invention provides a connector, a metal housing, and a manufacturing method thereof to more efficiently and economically use material during manufacturing.

Accordingly, the present invention provides a metal housing including a body and at least one ground pin. The ground pin is integrally formed with the body as a single piece, wherein the ground pin is formed by punching without a waste material being produced.

A method for manufacturing a metal housing without a waste material is provided, including steps of: providing a body; punching the body at a distance from a fringe of the body to cut out at least one strip; and bending the strip to form a ground pin.

Also, a connector is provided, including a base and the metal housing disclosed above. The metal housing covers the base. Further, a method for manufacturing the connector is provided, including steps of: forming a metal housing without a waste material being produced; and assembling the metal housing on the base.

In the connector, the metal housing and the manufacturing method thereof, the ground pin is at a distance from a fringe of the body, and is bent to protrude out of the fringe of the body so as to be fixed to a circuit board. The circuit board is applied to an electronic product, such as a computer or a switch hub. Several openings corresponding to the ground pin are formed after the stamping process. The metal housing is applied to a connector. The body has a plurality of holes respectively corresponding to a specified joint, such as an RJ-45 joint, an RJ-11 joint or a USB joint.

In the connector, the metal housing and the manufacturing method thereof of present invention, the strip has a cutting length which exceeds a predetermined distance. Furthermore, a body is punched to form a plurality of holes. The base has a plurality of receiving portions respectively corresponding to the holes, and the receiving portions electrically connect with the specified joints, respectively.

### BRIEF DESCRIPTION OF THE DRAWINGS

The invention can be more fully understood by reading the subsequent detailed description and examples with references made to the accompanying drawings, wherein:

FIG. 1A is a schematic view of a conventional metal housing;

FIG. 1B is side view of the metal housing shown in FIG. 1A before cutting;

FIG. 1C is a side view of the metal housing shown in FIG. 1B after cutting;

FIG. 2 is a schematic view of an embodiment of the metal housing of the present invention;

FIG. 3A is a side view of the metal housing shown in FIG. 2 after cutting out a strip;

FIG. 3B is a side view of the metal housing shown in FIG. 3A after bending the strip; FIGS. 4A and 4B are schematic views showing the connector of the present invention inserted onto a circuit board;

FIG. 4C is another view of the ground pin shown in FIG. 4B.

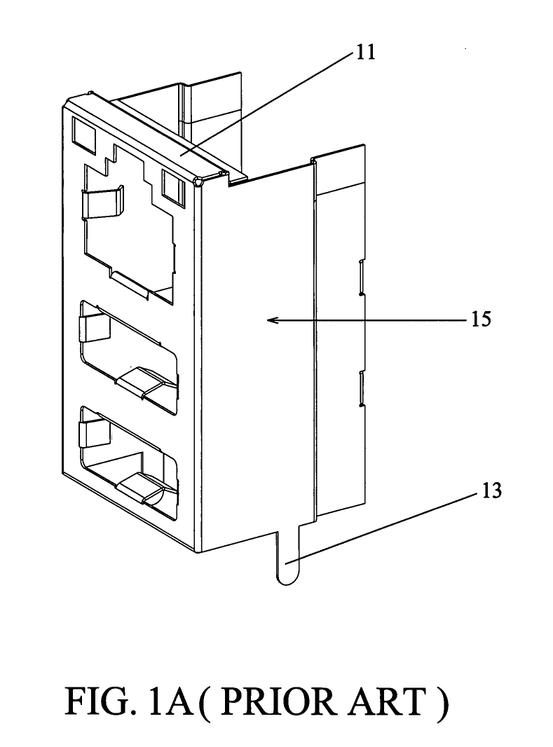

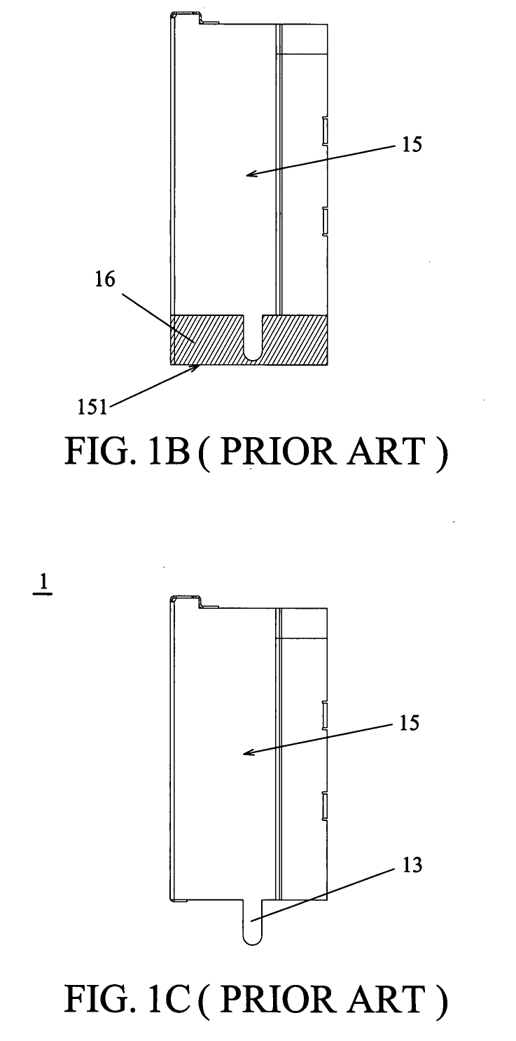

### DETAILED DESCRIPTION OF THE INVENTION

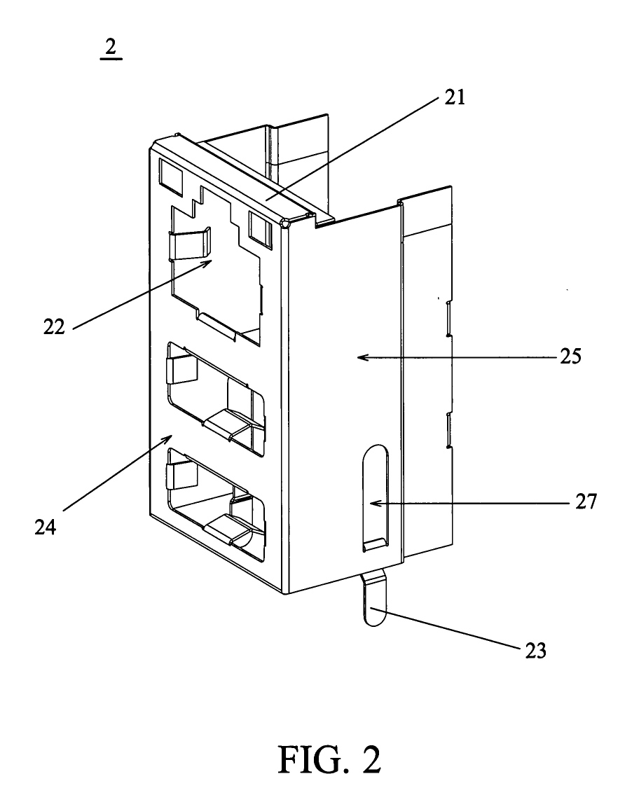

FIG. 2 is a schematic view of an embodiment of the metal housing of the present invention. Referring to FIG. 2, the metal housing 2 includes a body 21 and at least one ground pin 23. The ground pin 23 is integrally formed with the body 21 as a single piece. Additionally, the ground pin is formed by a punching process without a waste material being produced.

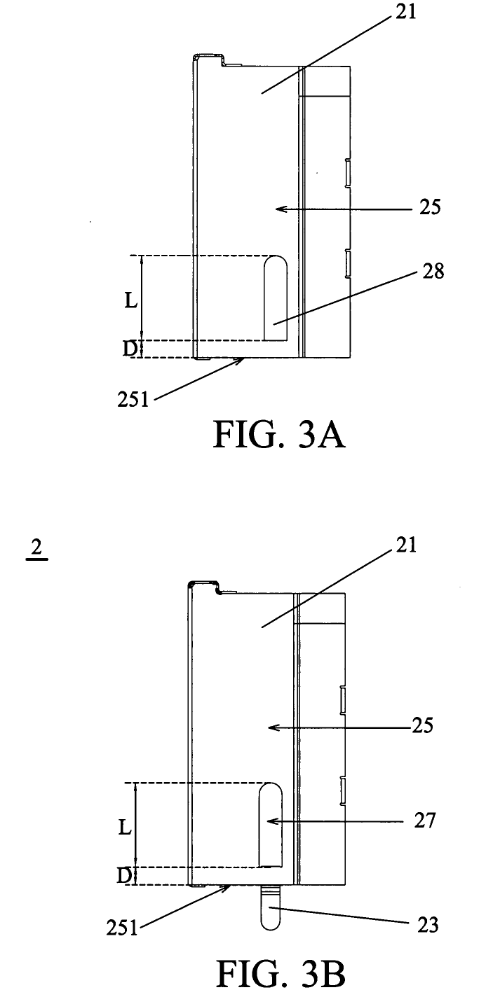

FIG. 3A is a side view of the metal housing shown in FIG. 2 after cutting out a strip. FIG. 3B is a side view of the metal housing shown in FIG. 3A after bending the strip. A method for manufacturing the metal housing 2 is provided as follow. At first, a body 21 is provided. At a predetermined distance D from a fringe 251 of the body 21, a strip 28 is cut out by punching the body 21. A cut length L of the strip 28 can be varied according to need, but it in necessary to exceed the predetermined distance D, such that the strip 28 is bent to protrude out of the fringe of the metal housing 2. Afterward, the strip 28 is bent toward the fringe 251 to form a ground pin 23. A portion of the ground protrudes out of the fringe 251. As shown in FIG. 2, a front surface 24 of the body 21 is punched to form a plurality of the holes 22, each of which corresponds to a specified joint, such as a RJ-45 joint, a RJ-11 joint or a USB joint.

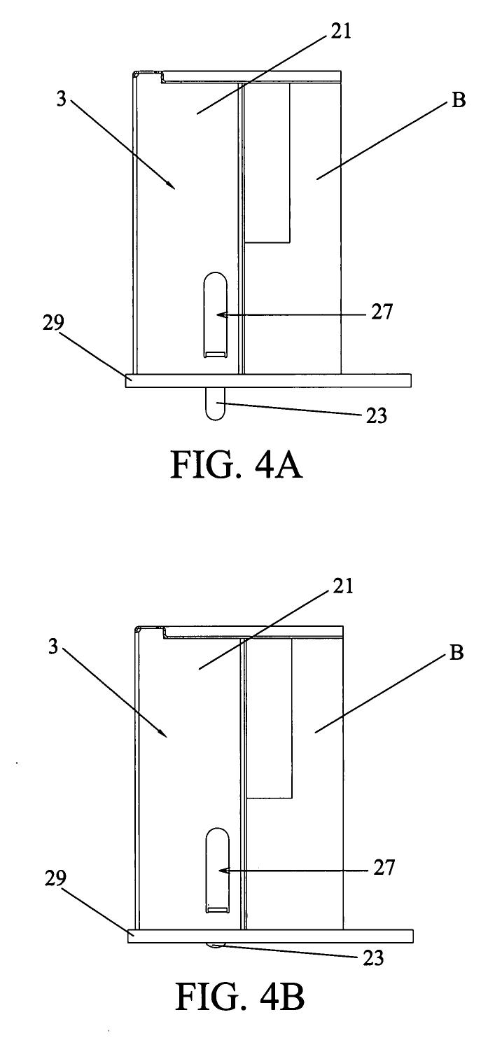

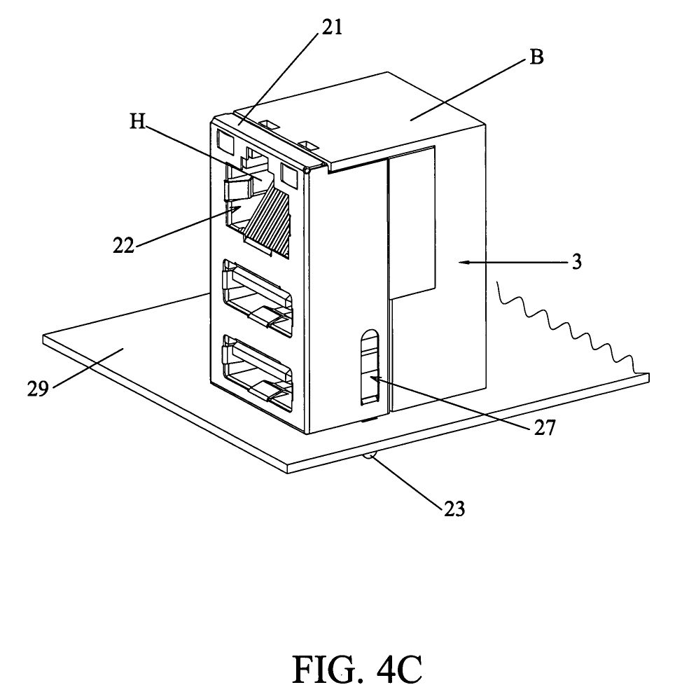

FIGS. 4A and 4B are schematic views showing the connector of the present invention inserted onto a circuit board; and FIG. 4C is another view of the ground pin shown in FIG. 4B. The metal housing 2 is applied to a connector 3. The connector is inserted onto a circuit board 29, and the strips 28 of the body 21 of the metal housing 2 is bent so as to form a ground pin 23 and allow the ground pin 23 to be fixed on the circuit 29. Also, since the base B has a plurality of receiving portions H respectively corresponding to the holes 22, when the specified joint is inserted in the hole 22, the joint is able to electrically connect with a bearing portion H within a base B. As a result, the connector 3 is able to be applied in an electronic product, such as a computer or a switch hub.

Accordingly, the metal housing 2 described provides a ground pin 23 with a varied length by adjusting the punching position, making the length of the ground pin 23 more adjustable and flexible. Additionally, the metal housing 2 does not produce a waste material, efficiently reducing material cost, and making the product more competitive.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A metal housing, comprising:
a body; and
at least one ground pin integrally formed with the body as a single piece;
wherein the ground pin is formed without a waste material being produced.

2. The metal housing as claimed in claim 1, wherein the ground pin is formed by a punching process.

3. The metal housing as claimed in claim 2, wherein the body further comprises a plurality of openings corresponding to the ground pin, and the openings are formed after the punching process.

4. The metal housing as claimed in claim 1, wherein the ground pin is bent to protrude out of a fringe of the body.

5. The metal housing as claimed in claim 1, wherein the ground pin is fixed to a circuit board, which is used in an electronic product, such as a computer or a switch hub.

6. The metal housing as claimed in claim 1, wherein the metal housing is applied to a connector, and the body comprises a plurality of holes, each of which corresponds to a specified joint, such as an RJ-45 joint, an RJ-11 joint or a USB joint.

7. A method for manufacturing a metal housing without a waste material being produced, comprising steps of:
providing a body;
processing the body at a predetermined distance from a fringe of the body to cut out at least one strip; and
bending the strip to form a ground pin protruding out of the fringe of the body.

8. The method as claimed in claim 7, wherein the strip is formed by a punching process.

9. The method as claimed in claim 8, wherein a plurality of openings corresponding to the ground pin are formed on the body after the punching process.

10. The method as claimed in claim 7, wherein the strip has a cutting length which exceeds the predetermined distance.

11. The method as claimed in claim 7, wherein the ground pin is fixed to a circuit board, which is used in an electronic product, such as a computer or a switch hub.

12. The method as claimed in claim 7, further comprising a step of: punching the body to form a plurality of holes, wherein the metal housing is applied to a connector, and each of the holes corresponds to a specified joint, such as an RJ-45 joint, an RJ-11 joint or a USB joint.

13. A connector, comprising:
a base; and
a metal housing covering the base, comprising:
a body; and
at least one ground pin integrally formed with the body as a single piece;
wherein the ground pin is formed without a waste material being produced.

14. The connector as claimed in claim 13, wherein the ground pin is formed by a punching process.

15. The connector as claimed in claim 14, wherein the body further comprises a plurality of openings corresponding to the ground pin, and the openings are formed after the punching process.

16. The connector as claimed in claim 13, wherein the ground pin is bent to protrude out of a fringe of the body.

17. The connector as claimed in claim 13, wherein the ground pin is fixed to a circuit board, which is used in an electronic product, such as a computer or a switch hub.

18. The connector as claimed in claim 13, wherein the body has a plurality of holes, each of which corresponds to a specified joint, such as an RJ-45 joint, an RJ-11 joint or a USB joint.

19. The connector as claimed in claim 18, wherein the base has a plurality of receiving portions respectively corresponding to the holes.

20. The connector as claimed in claim 19, wherein the receiving portions electrically connect with the specified joints, respectively.
